(19) United States
(12) Patent Application Publication
(10) Pub. No.: US 2024/0238895 A1
(43) Pub. Date: Jul. 18, 2024

(54) LASER OSCILLATING DEVICE

(71) Applicant: DISCO CORPORATION, Tokyo (JP)

(72) Inventors: Toshiyuki KITAMURA, Tokyo (JP); Keiji NOMARU, Tokyo (JP)

(21) Appl. No.: 18/413,229

(22) Filed: Jan. 16, 2024

(30) Foreign Application Priority Data
Jan. 17, 2023 (JP) 2023-005270

(51) Int. Cl. B23K 26/06; B23K 26/067; H01L 21/67

(52) U.S. Cl. CPC B23K 26/0652; B23K 26/0665; B23K 26/067; H01L 21/67092

(57) ABSTRACT

A laser oscillating device includes a signal laser oscillator for emitting a laser beam, a laser medium for amplifying the laser beam emitted from the signal laser oscillator, an exciting light introducing unit for introducing an exciting light into the laser medium, and a photonic crystal fiber for shaping the laser beam.

### BACKGROUND OF THE INVENTION

### Field of the Invention

The present invention relates to a laser oscillating device for amplifying and emitting a laser beam.

### Description of the Related Art

Wafers having a plurality of devices such as integrated circuits (ICs) and large scale integration (LSI) circuits formed in respective areas demarcated in a face side thereof by a grid of projected dicing lines are divided into individual device chips by a dicing apparatus or a laser processing apparatus. The individual device chips will be used in electronic devices such as cellular phones and personal computers.

A laser processing apparatus includes a chuck table for holding a wafer thereon, a laser beam applying unit for applying a laser beam to the wafer held on the chuck table, and a feed mechanism for processing-feeding the chuck table and the laser beam applying unit relatively to each other.

The laser beam applying unit includes a laser oscillating device for amplifying and emitting the laser beam, a beam condenser for converging the laser beam emitted from the laser oscillating device, and an optical system disposed between the laser oscillating device and the beam condenser. The laser beam applying unit is able to apply a desired laser beam to the wafer (see, for example, Japanese Patent Laid-open No. 2018-149571).

### SUMMARY OF THE INVENTION

The laser oscillating device includes a signal laser oscillator for emitting a laser beam as a seed beam, a laser medium for amplifying the laser beam emitted from the signal laser oscillator, an exciting light introducing unit for introducing an exciting light into the laser medium, and a pinhole mask for shaping the laser beam amplified by the laser medium.

However, since it is difficult for the pinhole mask to shape the profile of the radiation intensity of the laser beam into an ideal Gaussian distribution, the pinhole mask is unable to increase the quality of device chips produced from the wafer by the laser beam.

It is therefore an object of the present invention to provide a laser oscillating device that is capable of making the profile of the radiation intensity of a laser beam much closer to an ideal Gaussian distribution to thereby increase the quality of device chips produced from a workpiece by the laser beam.

In accordance with an aspect of the present invention, there is provided a laser oscillating device for amplifying and emitting a laser beam including a signal laser oscillator for emitting a laser beam, a laser medium for amplifying the laser beam emitted from the signal laser oscillator, an exciting light introducing unit for introducing an exciting light into the laser medium, and a photonic crystal fiber for shaping the laser beam.

Preferably, the photonic crystal fiber is interposed between the signal laser oscillator and the laser medium. The photonic crystal fiber may be disposed behind the laser medium. Preferably, the laser oscillating device further includes a condensing lens for converging and introducing the laser beam into the photonic crystal fiber.

Preferably, the laser oscillating device further includes a first condensing lens for converging the laser beam emitted from the signal laser oscillator and introducing the converged laser beam into the photonic crystal fiber, a first collimating lens for rectifying the laser beam that has passed through the photonic crystal fiber into a collimated beam, a second condensing lens for converging and introducing the laser beam that has passed through the first collimating lens into the laser medium, and a second collimating lens for rectifying the laser beam that has passed through the laser medium into a collimated beam.

Preferably, the exciting light introducing unit includes a first dichroic mirror interposed between the first collimating lens and the second condensing lens, for transmitting the laser beam therethrough and reflecting light of other wavelengths, an exciting light source for introducing the exciting light to the first dichroic mirror, and a second dichroic mirror for transmitting therethrough the laser beam that has passed through the second collimating lens and reflecting and excluding the light of other wavelengths.

Preferably, the laser oscillating device further includes a polarizing beam splitter for transmitting therethrough a P-polarized laser beam emitted from the signal laser oscillator, a first condensing lens for converging and introducing the P-polarized laser beam that has passed through the polarizing beam splitter into the laser medium, a first collimating lens for rectifying the P-polarized laser beam that has passed through the laser medium into a collimated beam, a second condensing lens for converging and introducing the P-polarized laser beam that has passed through the first collimating lens into the photonic crystal fiber, a second collimating lens for rectifying the P-polarized laser beam that has passed through the photonic crystal fiber into a collimated beam, a mirror for reflecting the P-polarized laser beam that has passed through the second collimating lens back to the second collimating lens, and a quarter-wave plate or a Faraday rotator interposed between the second collimating lens and the mirror, for converting a plane of polarization of the P-polarized laser beam to convert the P-polarized laser beam into an S-polarized laser beam.

Preferably, the exciting light introducing unit includes a first dichroic mirror interposed between the polarizing beam splitter and the first condensing lens, for transmitting the laser beam therethrough and reflecting light of other wavelengths, an exciting light source for introducing the exciting light to the first dichroic mirror, and a second dichroic mirror interposed between the first collimating lens and the second condensing lens, for transmitting the laser beam therethrough and reflecting and excluding the light of other wavelengths, in which the S-polarized laser beam that has been amplified is emitted from the polarizing beam splitter.

Preferably, the laser oscillating device further includes a second photonic crystal fiber disposed on an optical path for the amplified S-polarized laser beam emitted from the polarizing beam splitter.

Preferably, the condensing lens is replaced with a spatial-mode filtering unit for introducing the laser beam into the photonic crystal fiber.

Preferably, the spatial-mode filtering unit includes a pinhole mask and a filtering condensing lens for condensing and introducing the laser beam that has passed through the pinhole mask into the photonic crystal fiber.

Preferably, the spatial-mode filtering unit includes a pinhole mask, a first filtering condensing lens for condensing the laser beam to be introduced into the pinhole mask, a filtering collimating lens for rectifying the laser beam that has passed through the pinhole mask into a collimated beam, and a second filtering condensing lens for converging and introducing the collimated laser beam into the photonic crystal fiber.

Preferably, the exciting light introducing unit includes a first dichroic mirror for transmitting the laser beam therethrough and reflecting light of other wavelengths, an exciting light source for introducing the exciting light to the first dichroic mirror, and a second dichroic mirror for transmitting therethrough the laser beam that has passed through the laser medium and reflecting and excluding the light of other wavelengths.

Preferably, the laser oscillating device further includes two or more units each including the laser medium and the exciting light introducing unit, which are arranged in tandem.

Preferably, the laser oscillating device further includes an end mirror closing an end of the photonic crystal fiber such that the laser beam introduced into the photonic crystal fiber from the other end thereof is shaped when it is reflected by the end mirror and travels back through the photonic crystal fiber. Preferably, the laser oscillating device further includes a condensing lens disposed at the other end of the photonic crystal fiber and functioning as a collimating lens with respect to the laser beam reflected by the end mirror and returning from the photonic crystal fiber. Preferably, the laser oscillating device further includes a polarizing beam splitter disposed in front of the condensing lens and a quarter-wave plate or a Faraday rotator interposed between the condensing lens and the polarizing beam splitter.

Preferably, the photonic crystal fiber includes a first photonic crystal fiber and a second photonic crystal fiber, and the laser oscillating device further includes a first polarizing beam splitter for transmitting therethrough a P-polarized laser beam emitted from the signal laser oscillator, a first Faraday rotator and a half-wave plate for jointly converting a plane of polarization of the P-polarized laser beam, a second polarizing beam splitter for transmitting the P-polarized laser beam therethrough, a first condensing lens for converging and introducing the P-polarized laser beam that has passed through the second polarizing beam splitter into the laser medium, a first collimating lens for rectifying the P-polarized laser beam that has passed through the laser medium into a collimated beam, a second condensing lens for converging and introducing the P-polarized laser beam that has passed through the first collimating lens into the first photonic crystal fiber, a second collimating lens for rectifying the P-polarized laser beam that has passed through the first photonic crystal fiber into a collimated beam, a first mirror for reflecting the P-polarized laser beam that has passed through the second collimating lens back to the second collimating lens, a quarter-wave plate or a second Faraday rotator interposed between the second collimating lens and the first mirror, for converting the plane of polarization of the P-polarized laser beam to convert the P-polarized laser beam into an S-polarized laser beam, the second photonic crystal fiber being disposed on an optical path branched off at the second polarizing beam splitter, and a second mirror for reflecting the S-polarized laser beam that has passed through the second photonic crystal fiber back to the second photonic crystal fiber.

Preferably, the exciting light introducing unit includes a first dichroic mirror interposed between the second polarizing beam splitter and the first condensing lens, for transmitting the laser beam therethrough and reflecting light of other wavelengths, an exciting light source for introducing the exciting light to the first dichroic mirror, and a second dichroic mirror interposed between the first collimating lens and the second condensing lens, for transmitting the laser beam therethrough and reflecting and excluding the light of other wavelengths, the S-polarized laser beam from the quarter-wave plate or the second Faraday rotator is introduced from the second polarizing beam splitter into the second photonic crystal fiber and is reflected by the second mirror to return from the second photonic crystal fiber to the second polarizing beam splitter, the S-polarized laser beam that has returned to the second polarizing beam splitter passes through the first dichroic mirror, the first condensing lens, the laser medium, the first collimating lens, the second dichroic mirror, the second condensing lens, the first photonic crystal fiber, the second collimating lens, and the quarter-wave plate or the second Faraday rotator, and is reflected back by the first mirror, the plane of polarization of the S-polarized laser beam reflected back by the first mirror is converted from the S-polarized laser beam into a P-polarized laser beam by passing through the quarter-wave plate or the second Faraday rotator, and the P-polarized laser beam passes through the second polarizing beam splitter and thereafter is converted into an S-polarized laser beam by passing through the half-wave plate and the first Faraday rotator, and the S-polarized laser beam is emitted from the first polarizing beam splitter.

Inasmuch as the laser oscillating device according to the present invention includes the signal laser oscillator for emitting a laser beam, the laser medium for amplifying the laser beam emitted from the signal laser oscillator, the exciting light introducing unit for introducing an exciting light into the laser medium, and the photonic crystal fiber for shaping the laser beam, it is possible for the laser oscillating device to make the profile of the radiation intensity of the laser beam closer to an ideal Gaussian distribution for increasing the quality of device chips produced from a workpiece by the laser beam.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a laser processing apparatus incorporating a laser oscillating device according to the present invention;

FIG. 2 is a schematic diagram of a laser beam oscillating unit of the laser oscillating device illustrated in FIG. 1;

FIG. 3 is a schematic diagram of a laser oscillating device according to a first embodiment of the present invention;

FIG. 4 is a schematic diagram of a laser oscillating device according to a second embodiment of the present invention;

FIG. 5 is a schematic diagram of a laser oscillating device according to a third embodiment of the present invention;

FIG. 6 is a schematic diagram of a laser oscillating device according to a fourth embodiment of the present invention;

FIG. 7 is a schematic diagram of a laser oscillating device according to a fifth embodiment of the present invention;

FIG. 8 is a schematic diagram of an example of a spatial-mode filtering unit;

FIG. 9 is a schematic diagram of another example of the spatial-mode filtering unit;

FIG. 10 is a schematic diagram of an arrangement in which two units each including a laser medium and an exciting light introducing unit are disposed in series with each other;

FIG. 11 is a schematic diagram of an arrangement in which a condensing lens is disposed at an end of a photonic crystal fiber whose other end is closed by a mirror; and

FIG. 12 is a schematic diagram of an arrangement in which a polarizing beam splitter is disposed in front of the condensing lens illustrated in FIG. 11 and a quarter-wave plate or a Faraday rotator is disposed between the condensing lens and the polarizing beam splitter.

### DETAILED DESCRIPTION OF THE PREFERRED EMBODIMENTS

Identical parts are denoted by identical reference signs throughout views.

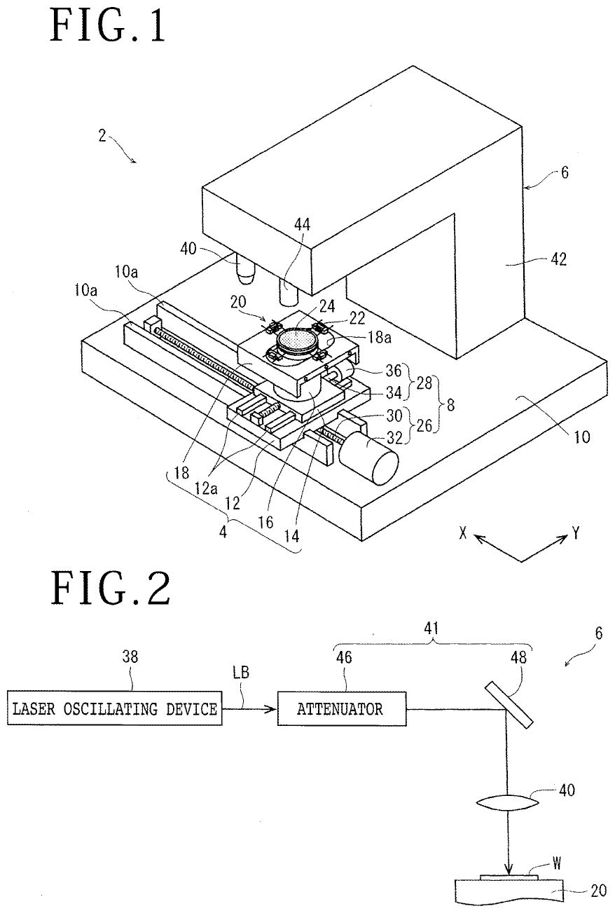

Laser oscillating devices according to preferred embodiments of the present invention will be described below with reference to the drawings. According to the present invention, a laser oscillating device is incorporated in a laser processing apparatus 2 illustrated in FIG. 1, for example. As illustrated in FIG. 1, the laser processing apparatus 2 includes holding means 4 for holding a workpiece such as a wafer, a laser beam applying unit 6 for applying a laser beam to the workpiece held by the holding means 4, and a feed mechanism 8 for moving the holding means 4 and the laser beam applying unit 6 relatively to each other.

The holding means 4 includes an X-axis movable plate 12 movably supported on an upper surface of a base 10 for movement along an X-axis indicated by the arrow X, a Y-axis movable plate 14 movably supported on an upper surface of the X-axis movable plate 12 for movement along a Y-axis indicated by the arrow Y, a support post 16 fixedly mounted on an upper surface of the Y-axis movable plate 14, and a cover plate 18 mounted on an upper end of the support post 16. The cover plate 18 has an oblong hole 18a defined therein that has a longitudinal axis extending along the Y-axis. A chuck table 20 that extends upwardly through the oblong hole 18a is mounted on an upper end of the support post 16. A plurality of clamps 22 that are angularly spaced at intervals circumferentially around the chuck table 20 are disposed on an outer circumferential edge of the chuck table 20.

A circular porous suction chuck 24 is disposed on an upper end surface of the chuck table 20. The suction chuck 24 is fluidly connected to suction means, not depicted, such as a vacuum pump. When the suction means is actuated, it generates and transmits a suction force to the suction chuck 24, holding the workpiece under suction on an upper surface thereof. The chuck table 20 is rotatable about its vertical central axis by an electric motor, not depicted, housed in the support post 16.

The X-axis and the Y-axis extend horizontally perpendicularly to each other and parallel to the upper surface of the base 10. The X-axis and the Y-axis jointly define an XY plane that lies substantially horizontally.

The feed mechanism 8 includes an X-axis feed mechanism 26 for processing-feeding the chuck table 20 along the X-axis and a Y-axis feed mechanism 28 for indexing-feeding the chuck table 20 along the Y-axis.

The X-axis feed mechanism 26 has a ball screw 30 coupled to the X-axis movable plate 12 and extending along the X-axis and an electric motor 32 for rotating the ball screw 30 about its central axis. The X-axis feed mechanism 26 converts rotary motion of the electric motor 32 into linear motion with the ball screw 30 and transmits the linear motion to the X-axis movable plate 12, moving the X-axis movable plate 12 along the X-axis along a pair of guide rails 10a on the base 10. The chuck table 20 on the X-axis movable plate 12 is thus processing-fed along the X-axis.

The Y-axis feed mechanism 28 has a ball screw 34 coupled to the Y-axis movable plate 14 and extending along the Y-axis and an electric motor 36 for rotating the ball screw 34 about its central axis. The Y-axis feed mechanism 28 converts rotary motion of the electric motor 36 into linear motion with the ball screw 34 and transmits the linear motion to the Y-axis movable plate 14, moving the Y-axis movable plate 14 along the Y-axis along a pair of guide rails 12a on the X-axis movable plate 12. The chuck table 20 on the Y-axis movable plate 14 is thus indexing-fed along the Y-axis.

The laser beam applying unit 6 will be described below with reference to FIGS. 1 and 2. The laser beam applying unit 6 includes a laser oscillating device 38 (see FIG. 2) according to the present invention for amplifying and emitting a laser beam LB, a beam condenser 40 (see FIG. 2) for converging the laser beam LB emitted from the laser oscillating device 38 and applying the converged laser beam LB to a workpiece W held by the holding means 4, and an optical system 41 (see FIG. 2) interposed between the laser oscillating device 38 and the beam condenser 40.

As illustrated in FIG. 1, the laser beam applying unit 6 has a housing 42 including a vertical column erected on the upper surface of the base 10 behind the holding means 4 and a horizontal beam extending substantially horizontally from an upper end portion of the vertical column in overhanging relation to the holding means 4. The laser oscillating device 38 is housed in the housing 42, and the beam condenser 40 is mounted on a lower surface of a distal end portion of the horizontal arm of the housing 42. An image capturing unit 44 for capturing an image of the workpiece W held by the holding means 4 is mounted on the lower surface of the distal end portion of the horizontal arm of the housing 42 adjacent to the beam condenser 40.

As illustrated in FIG. 2, the optical system 41 of the laser beam applying unit 6 includes an attenuator 46 for adjusting the power of the laser beam LB amplified and emitted from the laser oscillating device 38 and a mirror 48 for guiding the laser beam LB whose power has been adjusted by the attenuator 46 to the beam condenser 40.

The laser oscillating device 38 incorporated in the laser processing apparatus 2 is available in various different configurations that include, for example, laser oscillating devices 38A through 38E according to first through fifth embodiments of the present invention. The laser oscillating devices 38A through 38E according to the first through fifth embodiments will be described in detail below.

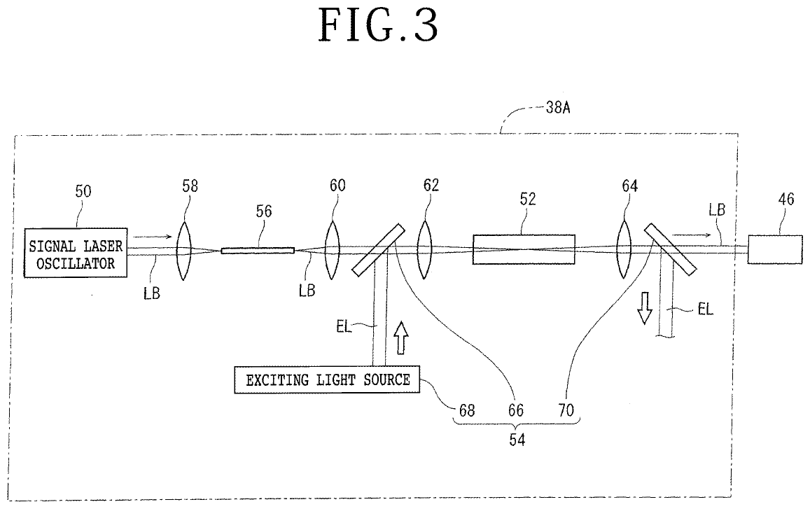

First, the laser oscillating device 38A according to the first embodiment will be described below with reference to FIG. 3. The laser oscillating device 38A includes a signal laser oscillator 50 for emitting a laser beam LB, a laser medium 52 for amplifying the laser beam LB emitted from the signal laser oscillator 50, an exciting light introducing unit 54 for introducing an exciting light EL into the laser medium 52, and a photonic crystal fiber 56 for shaping the laser beam LB.

The signal laser oscillator 50 emits the laser beam LB as a seed beam at a low output power level. The laser medium 52 is not limited to any particular type and may be an appropriate solid or gas medium. The photonic crystal fiber 56 is interposed between the signal laser oscillator 50 and the laser medium 52 according to the first embodiment. The photonic crystal fiber 56 may be of known nature.

The laser oscillating device 38A includes a first condensing lens 58 for converging and introducing the laser beam LB emitted from the signal laser oscillator 50 into the photonic crystal fiber 56, a first collimating lens 60 for rectifying the laser beam LB that has passed through the photonic crystal fiber 56 into a collimated beam, a second condensing lens 62 for converging and introducing the laser beam LB that has passed through the first collimating lens 60 into the laser medium 52, and a second collimating lens 64 for rectifying the laser beam LB that has passed through the laser medium 52 into a collimated beam.

The exciting light introducing unit 54 is of the coaxial excitation type including a first dichroic mirror 66 for transmitting the laser beam LB therethrough and reflecting light of other wavelengths, an exciting light source 68 for applying the exciting light EL to the first dichroic mirror 66, and a second dichroic mirror 70 for transmitting therethrough the laser beam LB that has passed through the laser medium 52 and reflecting and excluding light of other wavelengths. The exciting light introducing unit 54 is not limited to the coaxial excitation type, and may be of the side excitation type in which it applies an exciting light to a side surface of the laser medium 52.

The first and second dichroic mirrors 66 and 70 transmit therethrough the laser beam LB emitted from the signal laser oscillator 50, but reflect light of other wavelengths than the wavelength of the laser beam LB emitted from the signal laser oscillator 50.

According to the first embodiment, as illustrated in FIG. 3, the first dichroic mirror 66 is interposed between the first collimating lens 60 and the second condensing lens 62. The second dichroic mirror 70 transmits therethrough the laser beam LB that has passed through the second collimating lens 64.

The exciting light EL emitted from the exciting light source 68 may be a semiconductor laser beam, for example. The wavelength of the exciting light EL may be slightly shorter than the wavelength of the laser beam LB emitted from the signal laser oscillator 50.

According to the first embodiment, the laser beam LB emitted from the signal laser oscillator 50 is converged by the first condensing lens 58 and introduced into the photonic crystal fiber 56. The photonic crystal fiber 56 shapes the laser beam LB to make the profile of its radiation intensity closer to an ideal Gaussian distribution.

Although the radiation intensity profile of the laser beam LB shaped by the photonic crystal fiber 56 slightly deviates from the ideal Gaussian distribution, it is closer to the ideal Gaussian distribution than the radiation intensity profile of a laser beam shaped by a pinhole mask.

The laser beam LB that has passed through the photonic crystal fiber 56 is rectified into a collimated beam by the first collimating lens 60, then passes through the first dichroic mirror 66, is converged by the second condensing lens 62, and is thereafter introduced into the laser medium 52.

Since the exciting light EL is reflected by the first dichroic mirror 66 and introduced into the laser medium 52, the laser beam LB is amplified by the laser medium 52. The amplified laser beam LB is rectified into a collimated beam by the second collimating lens 64, passes through the second dichroic mirror 70, and is thereafter introduced into the attenuator 46.

Any part of the exciting light EL that has not been absorbed by the laser medium 52 passes through the second collimating lens 64 and is then reflected and excluded by the second dichroic mirror 70. Therefore, the excluded exciting light EL is not introduced into the attenuator 46.

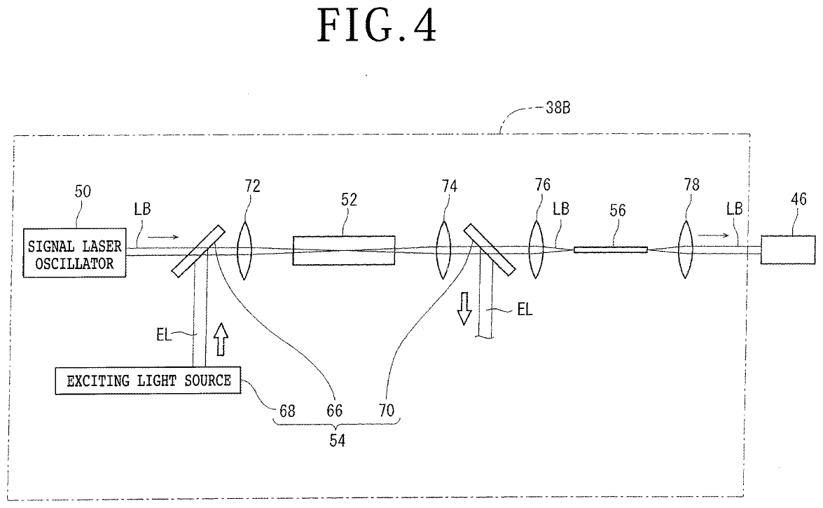

The laser oscillating device 38B according to the second embodiment will be described below with reference to FIG. 4. The laser oscillating device 38B according to the second embodiment includes a signal laser oscillator 50, a laser medium 52, an exciting light introducing unit 54, and a photonic crystal fiber 56, as with the first embodiment. The second embodiment is different from the first embodiment in that the photonic crystal fiber 56 is positioned downstream of the laser medium 52 along the main optical path from the signal laser oscillator 50 toward the attenuator 46.

The laser oscillating device 38B includes a first condensing lens 72 for converging and introducing the laser beam LB emitted from the signal laser oscillator 50 into the laser medium 52, a first collimating lens 74 for rectifying the laser beam LB that has passed through the laser medium 52 into a collimated beam, a second condensing lens 76 for converging and introducing the laser beam LB that has passed through the first collimating lens 74 into the photonic crystal fiber 56, and a second collimating lens 78 for rectifying the laser beam LB that has passed through the photonic crystal fiber 56 into a collimated beam.

According to the second embodiment, the first dichroic mirror 66 of the exciting light introducing unit 54 is interposed between the signal laser oscillator 50 and the first condensing lens 72, and the second dichroic mirror 70 of the exciting light introducing unit 54 is interposed between the first collimating lens 74 and the second condensing lens 76.

According to the second embodiment, the laser beam LB emitted from the signal laser oscillator 50 passes through the first dichroic mirror 66, is converged by the first condensing lens 72 and introduced into the laser medium 52, and is amplified by the laser medium 52.

The amplified laser beam LB is rectified into a collimated beam by the first collimating lens 74, passes through the second dichroic mirror 70, and is thereafter converged by the second condensing lens 76 and introduced into the photonic crystal fiber 56.

The photonic crystal fiber 56 shapes the laser beam LB to make the profile of its radiation intensity closer to the ideal Gaussian distribution. The shaped laser beam LB is rectified into a collimated beam by the second collimating lens 78 and introduced into the attenuator 46.

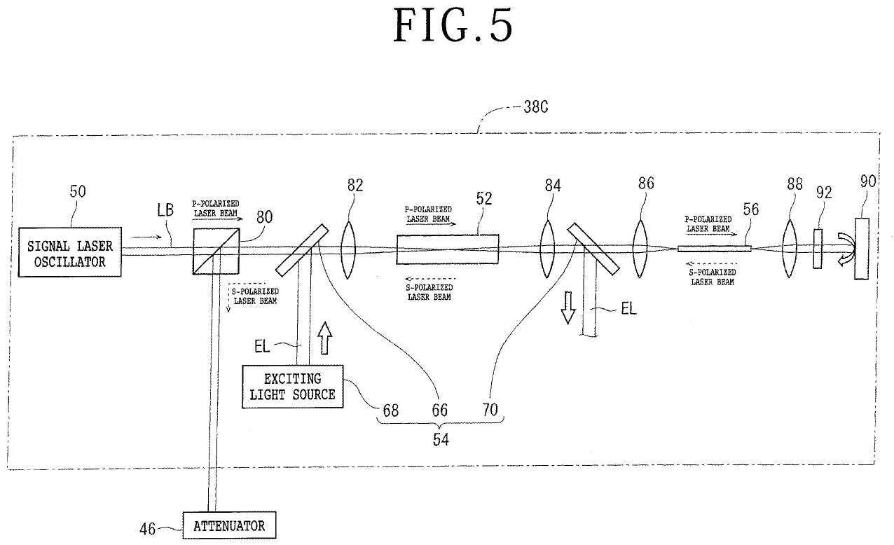

The laser oscillating device 38C according to the third embodiment will be described below with reference to FIG. 5. The laser oscillating device 38C according to the third embodiment includes a signal laser oscillator 50, a laser medium 52, an exciting light introducing unit 54, and a photonic crystal fiber 56, the photonic crystal fiber 56 being positioned downstream of the laser medium 52 along the main optical path, as with the second embodiment. According to the third embodiment, the laser beam LB emitted from the signal laser oscillator 50 is a P-polarized laser beam LB with respect to a polarizing beam splitter 80 to be described below.

According to the third embodiment, the laser oscillating device 38C additionally includes the polarizing beam splitter 80, a mirror 90, and a quarter-wave plate 92. The quarter-wave plate 92 may be replaced with a Faraday rotator.

Specifically, the laser oscillating device 38C includes the polarizing beam splitter 80 for transmitting therethrough the P-polarized laser beam LB emitted from the signal laser oscillator 50, a first condensing lens 82 for converging and introducing the laser beam LB that has passed through the polarizing beam splitter 80 into the laser medium 52, a first collimating lens 84 for rectifying the laser beam LB that has passed through the laser medium 52 into a collimated beam, a second condensing lens 86 for converging and introducing the laser beam LB that has passed through the first collimating lens 84 into the photonic crystal fiber 56, a second collimating lens 88 for rectifying the laser beam LB that has passed through the photonic crystal fiber 56 into a collimated beam, the mirror 90 for reflecting the laser beam LB that has passed through the second collimating lens 88 back to the second collimating lens 88, and the quarter-wave plate 92 interposed between the second collimating lens 88 and the mirror 90 for converting the plane of polarization of the laser beam LB from linear polarization to circular polarization and reversing the direction of rotation of the circularly polarized laser beam LB to convert the laser beam LB from the P-polarized beam to an S-polarized beam.

The first condensing lens 82 and the first collimating lens 84 may be identical in structure to each other. With respect to the returning laser beam LB reflected by the mirror 90, the first condensing lens 82 functions as a collimating lens, and the first collimating lens 84 functions as a condensing lens.

Similarly, the second condensing lens 86 and the second collimating lens 88 may be identical in structure to each other. With respect to the returning laser beam LB reflected by the mirror 90, the second condensing lens 86 functions as a collimating lens, and the second collimating lens 88 functions as a condensing lens.

According to the third embodiment, the first dichroic mirror 66 of the exciting light introducing unit 54 is interposed between the polarizing beam splitter 80 and the first condensing lens 82, and the second dichroic mirror 70 of the exciting light introducing unit 54 can be interposed between the first collimating lens 84 and the second condensing lens 86.

According to the third embodiment, the P-polarized laser beam LB emitted from the signal laser oscillator 50 passes through the polarizing beam splitter 80 and the first dichroic mirror 66. Then, the P-polarized laser beam LB is converged by the first condensing lens 82 and introduced into the laser medium 52, and is amplified by the laser medium 52.

The amplified P-polarized laser beam LB is rectified into a collimated beam by the first collimating lens 84, passes through the second dichroic mirror 70, and is thereafter converged by the second condensing lens 86 and introduced into the photonic crystal fiber 56. The photonic crystal fiber 56 shapes the P-polarized laser beam LB to make the profile of its radiation intensity closer to the ideal Gaussian distribution (first shaping).

The shaped P-polarized laser beam LB is rectified into a collimated beam by the second collimating lens 88, passes through the quarter-wave plate 92, and is thereafter reflected by the mirror 90. Then, the reflected laser beam LB passes again through the quarter-wave plate 92. Since the laser beam LB passes twice through the quarter-wave plate 92, the plane of polarization of the laser beam LB that was P-polarized before passing through the quarter-wave plate 92 is converted to the S-polarized laser beam LB.

The laser beam LB that has been converted to the S-polarized laser beam is converged by the second collimating lens 88, introduced into the photonic crystal fiber 56, and shaped again by the photonic crystal fiber 56 (second shaping).

According to the third embodiment, as described above, the laser beam LB is shaped twice by the photonic crystal fiber 56. Consequently, it is possible, according to the third embodiment, to make the profile of the radiation intensity of the laser beam LB much closer to the ideal Gaussian distribution than that according to the first and second embodiments.

According to the third embodiment, furthermore, inasmuch as the laser beam LB travels to and from the photonic crystal fiber 56, the laser beam LB is shaped more often than that according to the second embodiment with a simple optical system that requires no more photonic crystal fibers 56.

The reshaped S-polarized laser beam LB is rectified into a collimated beam by the second condensing lens 86, passes through the second dichroic mirror 70, is thereafter condensed by the first collimating lens 84, and introduced into the laser medium 52, in which the S-polarized laser beam LB is amplified again.

The S-polarized laser beam LB that has been amplified again by the laser medium 52 is rectified into a collimated beam by the first condensing lens 82, passes through the first dichroic mirror 66, and is thereafter introduced into the polarizing beam splitter 80. Since the laser beam LB is S-polarized, its optical path is changed by the polarizing beam splitter 80 such that the laser beam LB is introduced into the attenuator 46. According to the third embodiment, therefore, the laser oscillating device 38C emits the amplified S-polarized laser beam LB from the polarizing beam splitter 80.

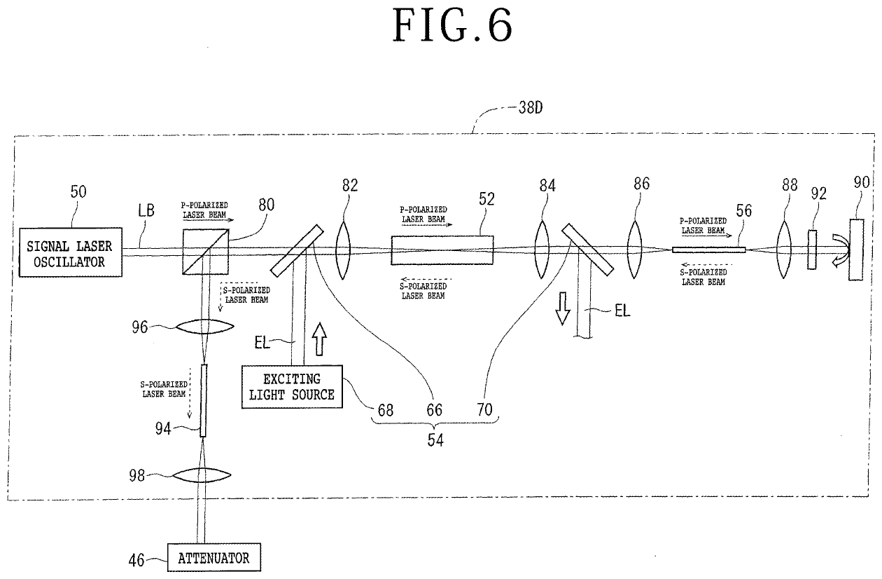

The laser oscillating device 38D according to the fourth embodiment will be described below with reference to FIG. 6. The laser oscillating device 38D according to the fourth embodiment includes a signal laser oscillator 50, a laser medium 52, an exciting light introducing unit 54, and a photonic crystal fiber 56, the photonic crystal fiber 56 being positioned downstream of the laser medium 52 along the main optical path, as with the second and third embodiments. According to the fourth embodiment, the laser beam LB emitted from the signal laser oscillator 50 is a P-polarized laser beam LB with respect to a polarizing beam splitter 80, as with the third embodiment.

According to the fourth embodiment, the laser oscillating device 38D additionally includes the polarizing beam splitter 80, a first condensing lens 82, a first collimating lens 84, a second condensing lens 86, a second collimating lens 88, a mirror 90, and a quarter-wave plate 92, as with the third embodiment. The quarter-wave plate 92 may be replaced with a Faraday rotator, as with the third embodiment.

The laser oscillating device 38D according to the fourth embodiment is essentially identical in structure to the laser oscillating device 38C according to the third embodiment. According to the fourth embodiment, however, the laser oscillating device 38D further includes a photonic crystal fiber 94 on the optical path of the amplified S-polarized laser beam LB emitted from the polarizing beam splitter 80. In other words, the laser oscillating device 38D according to the fourth embodiment has the two photonic crystal fibers 56 and 94.

According to the fourth embodiment, of the two photonic crystal fibers 56 and 94, the photonic crystal fiber 56 is referred to as “first photonic crystal fiber 56” whereas the photonic crystal fiber 94 as “second photonic crystal fiber” for illustrative purposes.

As illustrated in FIG. 6, a third condensing lens 96 is positioned in front of, i.e., upstream of, the second photonic crystal fiber 94, for converging the laser beam LB whose optical path has been changed by the polarizing beam splitter 80 and introducing the laser beam LB into the second photonic crystal fiber 94. Furthermore, a third collimating lens 98 is disposed behind, i.e., downstream of, the second photonic crystal fiber 94, for rectifying the laser beam LB that has passed through the second photonic crystal fiber 94 into a collimated beam. The third condensing lens 96 and the third collimating lens 98 may be identical in structure to each other.

According to the fourth embodiment, as with the third embodiment, the P-polarized laser beam LB emitted from the signal laser oscillator 50 passes through the polarizing beam splitter 80 and the first dichroic mirror 66. Then, the P-polarized laser beam LB is converged by the first condensing lens 82, introduced into the laser medium 52, and amplified by the laser medium 52.

The amplified P-polarized laser beam LB is rectified into a collimated beam by the first collimating lens 84, passes through the second dichroic mirror 70, and is thereafter converged by the second condensing lens 86 and introduced into the first photonic crystal fiber 56. The first photonic crystal fiber 56 shapes the P-polarized laser beam LB to make the profile of its radiation intensity closer to the ideal Gaussian distribution (first shaping).

The shaped P-polarized laser beam LB is rectified into a collimated beam by the second collimating lens 88, passes through the quarter-wave plate 92, and is thereafter reflected by the mirror 90. Then, the reflected laser beam LB passes again through the quarter-wave plate 92. Since the laser beam LB passes twice through the quarter-wave plate 92, the plane of polarization of the laser beam LB that was P-polarized before passing through the quarter-wave plate 92 is converted to the S-polarized laser beam LB.

The laser beam LB whose plane of polarization has been converted to S polarization is converged by the second collimating lens 88, introduced into the photonic crystal fiber 56, and shaped again by the photonic crystal fiber 56 (second shaping).

The reshaped S-polarized laser beam LB is rectified into a collimated beam by the second condensing lens 86, passes through the second dichroic mirror 70, is thereafter condensed by the first collimating lens 84, and is introduced into the laser medium 52, in which the S-polarized laser beam LB is amplified again.

The S-polarized laser beam LB that has been amplified again by the laser medium 52 is rectified into a collimated beam by the first condensing lens 82, passes through the first dichroic mirror 66, and is thereafter introduced into the polarizing beam splitter 80. Since the laser beam LB is S-polarized, its optical path is changed by the polarizing beam splitter 80.

The S-polarized laser beam LB whose optical path has been changed by the polarizing beam splitter 80 is converged by the third condensing lens 96, is introduced into the second photonic crystal fiber 94, and is then shaped again by the second photonic crystal fiber 94 (third shaping). The S-polarized laser beam LB that has been shaped three times is rectified into a collimated beam by the third collimating lens 98 and is introduced into the attenuator 46.

According to the fourth embodiment, as described above, the laser beam LB is shaped three times by the first and second photonic crystal fibers 56 and 94. Therefore, it is possible according to the fourth embodiment to make the profile of the radiation intensity of the laser beam LB much closer to the ideal Gaussian distribution than that according to the first through third embodiments.

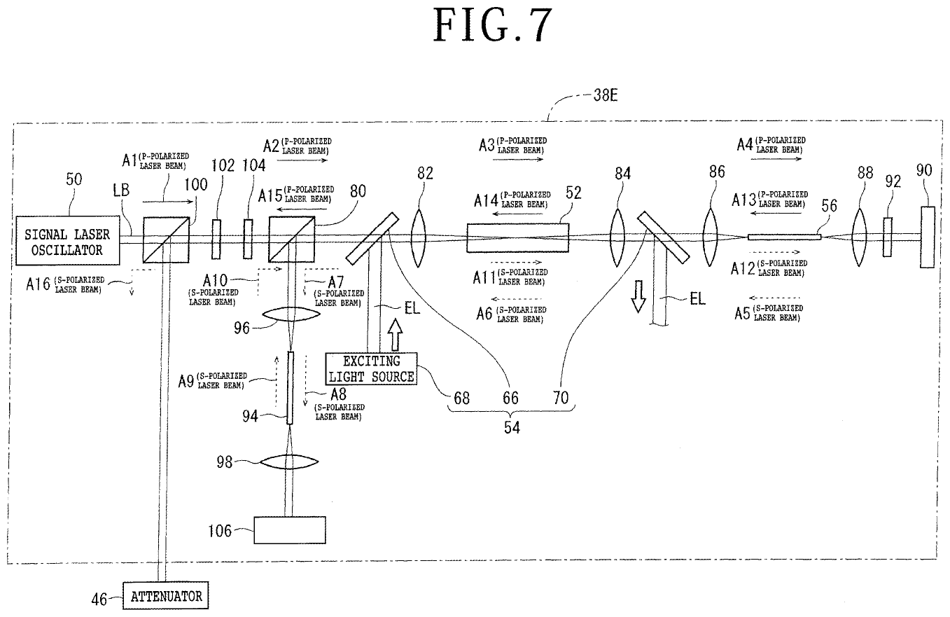

The laser oscillating device 38E according to the fifth embodiment will be described below with reference to FIG. 7. The laser oscillating device 38E according to the fifth embodiment includes a signal laser oscillator 50, a laser medium 52, an exciting light introducing unit 54, and first and second photonic crystal fibers 56 and 94, the first photonic crystal fiber 56 being positioned downstream of the laser medium 52 along the main optical path, as with the fourth embodiment. According to the fifth embodiment, the laser beam LB emitted from the signal laser oscillator 50 is a P-polarized laser beam LB with respect to a first polarizing beam splitter 100, as with the third and fourth embodiments.

As understood from a comparison between FIGS. 6 and 7, the laser oscillating device 38E according to the fifth embodiment is essentially identical in structure to the laser oscillating device 38D according to the fourth embodiment. According to the fifth embodiment, however, the laser oscillating device 38E includes, in addition to the components according to the fourth embodiment, a first polarizing beam splitter 100, a first Faraday rotator 102, a half-wave plate 104, and a second mirror 106.

Specifically, the laser oscillating device 38E according to the fifth embodiment includes a first polarizing beam splitter 100 for transmitting therethrough the P-polarized laser beam LB emitted from the signal laser oscillator 50, a first Faraday rotator 102 and a half-wave plate 104 for jointly converting the plane of polarization of the laser beam LB, a second polarizing beam splitter 80 for transmitting the P-polarized laser beam LB therethrough, a first condensing lens 82 for converging and introducing the laser beam LB that has passed through the second polarizing beam splitter 80 into the laser medium 52, a first collimating lens 84 for rectifying the laser beam LB that has passed through the laser medium 52 into a collimated beam, a second condensing lens 86 for converging and introducing the laser beam LB that has passed through the first collimating lens 84 into the first photonic crystal fiber 56, a second collimating lens 88 for rectifying the laser beam LB that has passed through the first photonic crystal fiber 56 into a collimated beam, a first mirror 90 for reflecting the laser beam LB that has passed through the second collimating lens 88 back to the second collimating lens 88, a quarter-wave plate 92 interposed between the second collimating lens 88 and the first mirror 90 for converting the plane of polarization of the laser beam LB from P polarization to the S-polarized laser beam LB, a second photonic crystal fiber 94 disposed on an optical path branched off at the second polarizing beam splitter 80, and a second mirror 106 for reflecting the laser beam LB introduced into and emitted from the second photonic crystal fiber 94 back to the second photonic crystal fiber 94. The quarter-wave plate 92 may be replaced with a second Faraday rotator.

The first Faraday rotator 102 and the half-wave plate 104 convert the plane of polarization of the laser beam LB when the laser beam LB passes through the half-wave plate 104 and the first Faraday rotator 102 in the order named. Conversely, the first Faraday rotator 102 and the half-wave plate 104 do not convert the plane of polarization of the laser beam LB when the laser beam LB passes through the first Faraday rotator 102 and the half-wave plate 104 in the order named.

According to the fifth embodiment, as with the fourth embodiment, of the two photonic crystal fibers 56 and 94, the photonic crystal fiber 56 is referred to as “first photonic crystal fiber 56” whereas the photonic crystal fiber 94 as “second photonic crystal fiber 94.” A third condensing lens 96 is disposed in front of the second photonic crystal fiber 94, and a third collimating lens 98 is disposed behind the second photonic crystal fiber 94.

According to the fifth embodiment, with respect to the returning laser beam LB reflected by the second mirror 106, the third condensing lens 96 functions as a collimating lens, and the third collimating lens 98 functions as a condensing lens.

According to the fifth embodiment, unlike the fourth embodiment, the laser oscillating device 38E includes the two polarizing beam splitters 80 and 100 and the two mirrors 90 and 106. Therefore, “the polarizing beam splitter 80” and “the mirror 90” according to the fourth embodiment are referred to respectively as “the second polarizing beam splitter 80” and “the first mirror 90” according to the fifth embodiment.

According to the fifth embodiment, the P-polarized laser beam LB emitted from the signal laser oscillator 50 passes through the first polarizing beam splitter 100, as indicated by the arrow A1 in FIG. 7.

Then, the P-polarized laser beam LB passes through the first Faraday rotator 102 and the half-wave plate 104. At this time, since the P-polarized laser beam LB passes through the first Faraday rotator 102 and then through the half-wave plate 104, the plane of polarization of the P-polarized laser beam LB is not converted and remains P—polarized.

Then, the P-polarized laser beam LB passes through the second polarizing beam splitter 80 and the first dichroic mirror 66, as indicated by the arrow A2. Then, the P-polarized laser beam LB is converged by the first condensing lens 82 and introduced into the laser medium 52, as indicated by the arrow A3, and is amplified by the laser medium 52 (first amplification).

The P-polarized laser beam LB that has been amplified once is rectified into a collimated beam by the first collimating lens 84, then passes through the second dichroic mirror 70, and is converged by the second condensing lens 86 and introduced into the first photonic crystal fiber 56, as indicated by the arrow A4. The first photonic crystal fiber 56 shapes the P-polarized laser beam LB to make the profile of its radiation intensity closer to the ideal Gaussian distribution (first shaping).

The P-polarized laser beam LB that has been shaped once is rectified into a collimated beam by the second collimating lens 88, then passes through the quarter-wave plate 92, and is reflected by the first mirror 90. The reflected P-polarized laser beam LB passes again through the quarter-wave plate 92. Since the laser beam LB passes twice through the quarter-wave plate 92, the plane of polarization of the laser beam LB that was P-polarized before passing through the quarter-wave plate 92 is converted to the S-polarized laser beam LB.

The laser beam LB thus converted to an S-polarized laser beam is converged by the second collimating lens 88 and introduced into the first photonic crystal fiber 56, as indicated by the arrow A5, that shapes the S-polarized laser beam LB again (second shaping).

The S-polarized laser beam LB that has been shaped twice is rectified into a collimated beam by the second collimating lens 88, then passes through the second dichroic mirror 70, is thereafter converged by the first collimating lens 84 and introduced into the laser medium 52, as indicated by the arrow A6, and is amplified again in the laser medium 52 (second amplification).

The S-polarized laser beam LB that has been amplified twice is rectified into a collimated beam by the first condensing lens 82, then passes through the first dichroic mirror 66, and is thereafter introduced into the second polarizing beam splitter 80. Inasmuch as the introduced laser beam LB is S-polarized, the second polarizing beam splitter 80 converts its optical path to a branch optical path, as indicated by the arrow A7.

The S-polarized laser beam LB is applied along the branch optical path to the third condensing lens 96 that converges the S-polarized laser beam LB. The S-polarized laser beam LB is then introduced into the second photonic crystal fiber 94, as indicated by the arrow A8, and is further shaped by the second photonic crystal fiber 94 (third shaping).

The S-polarized laser beam LB that has been shaped three times is rectified into a collimated beam by the third collimating lens 98, and is thereafter reflected by the second mirror 106. The reflected S-polarized laser beam LB is converged by the third collimating lens 98 and introduced into the second photonic crystal fiber 94, as indicated by the arrow A9, and is shaped further by the second photonic crystal fiber 94 (fourth shaping).

The S-polarized laser beam LB that has been shaped four times is rectified into a collimated beam by the third condensing lens 96, and has its optical path changed by the second polarizing beam splitter 80, as indicated by the arrow A10. The S-polarized laser beam LB whose optical path has been changed passes through the first dichroic mirror 66, is thereafter converged by the first condensing lens 82 and introduced into the laser medium 52, as indicated by the arrow A11, and is amplified by the laser medium 52 (third amplification).

The S-polarized laser beam LB that has been amplified three times is rectified into a collimated beam by the first collimating lens 84 and then passes through the second dichroic mirror 70. The S-polarized laser beam LB is then converged by the second condensing lens 86 and introduced into the first photonic crystal fiber 56, as indicated by the arrow A12, and is shaped further by the first photonic crystal fiber 56 (fifth shaping).

The S-polarized laser beam LB that has been shaped five times is rectified into a collimated beam by the second collimating lens 88, passes through the quarter-wave plate 92, and is thereafter reflected by the first mirror 90. The reflected S-polarized laser beam LB passes again through the quarter-wave plate 92. Since the laser beam LB passes twice through the quarter-wave plate 92, the plane of polarization of the laser beam LB that was P-polarized before passing through the quarter-wave plate 92 is converted to make the laser beam LB P-polarized.

The laser beam LB thus converted to a P-polarized beam is converged by the second collimating lens 88, is introduced into the first photonic crystal fiber 56, as indicated by the arrow A13, and is shaped further by the first photonic crystal fiber 56 (sixth shaping).

The P-polarized laser beam LB that has been shaped six times is rectified into a collimated beam by the second condensing lens 86, then passes through the second dichroic mirror 70, and is thereafter converged by the first collimating lens 84 and introduced into the laser medium 52, as indicated by the arrow A14. The P-polarized laser beam LB is amplified further by the laser medium 52 (fourth amplification).

The P-polarized laser beam LB that has been amplified four times is rectified into a collimated beam by the first condensing lens 82 and then passes through the first dichroic mirror 66 and the second polarizing beam splitter 80, as indicated by the arrow A15.

Then, the P-polarized laser beam LB passes through the half-wave plate 104 and the first Faraday rotator 102. At this time, since the P-polarized laser beam LB passes through the half-wave plate 104 and then through the first Faraday rotator 102, the plane of polarization of the P-polarized laser beam LB is converted to make the laser beam LB S-polarized.

The laser beam LB that has been converted to the S-polarized laser beam has its optical path converted by the first polarizing beam splitter 100 and is introduced into the attenuator 46, as indicated by the arrow A16. According to the fifth embodiment, the laser oscillating device 38E emits the amplified S-polarized laser beam LB from the first polarizing beam splitter 100.

According to the fifth embodiment, the laser beam LB is shaped a total of six times by the first and second photonic crystal fibers 56 and 94. According to the fifth embodiment, consequently, the profile of the radiation intensity of the laser beam LB becomes far closer to the ideal Gaussian distribution than that according to the first through fourth embodiments.

According to the fifth embodiment, furthermore, inasmuch as the laser beam LB travels to and from not only the first photonic crystal fiber 56 but also the second photonic crystal fiber 94, the laser beam LB is shaped more often than that according to the fourth embodiment with a simple optical system that requires no more photonic crystal fibers 56.

As described above, either one of the laser oscillating devices 38A through 38E according to the first through fifth embodiments includes the signal laser oscillator 50 for emitting the laser beam LB, the exciting light introducing unit 54 for introducing the exciting light EL into the laser medium 52, and the photonic crystal fiber 56 for shaping the laser beam LB. The oscillating devices 38A through 38E are thus capable of making the profile of the radiation intensity of the laser beam LB closer to the ideal Gaussian distribution for increasing the quality of device chips produced from the workpiece W by the laser beam LB.

The laser oscillating devices 38A through 38E according to the first through fifth embodiments are not limited to the structural details described above, but may be changed or modified within the scope of the present invention.

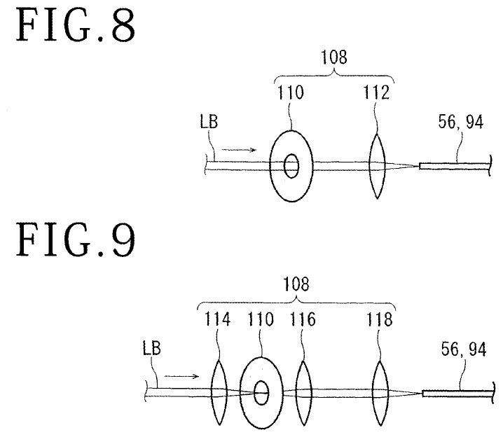

According to the first through fifth embodiments, the laser oscillating devices 38A through 38E include the condensing lens for converging and introducing the laser beam LB into the photonic crystal fiber 56 and 94. However, the condensing lens may be replaced with a spatial-mode filtering unit 108 (see FIGS. 8 and 9) for introducing the laser beam LB into the photonic crystal fiber 56 and 94.

As illustrated in FIG. 8, the spatial-mode filtering unit 108 includes, for example, a pinhole mask 110 and a filtering condensing lens 112 for converging the laser beam LB that has passed through the pinhole mask 110 and introducing the converged laser beam LB into the photonic crystal fiber 56 and 94.

Alternatively, as illustrated in FIG. 9, the spatial-mode filtering unit 108 includes, for example, a pinhole mask 110, a first filtering condensing lens 114 for converging the laser beam LB to be introduced into the pinhole mask 110, a filtering collimating lens 116 for rectifying the laser beam LB that has passed through the pinhole mask 110 into a collimated beam, and a second filtering condensing lens 118 for converging and introducing the collimated laser beam LB into the photonic crystal fiber 56 and 94.

The spatial-mode filtering unit 108 described above is effective to prevent the end face of the photonic crystal fiber 56 and 94 from being damaged particularly when the laser oscillating device is used in high output power applications.

The condensing lens that may be replaced with the spatial-mode filtering unit refers to the first condensing lens 58 according to the first embodiment, the second condensing lens 76 according to the second embodiment, the second condensing lens 86 according to the third embodiment, and the second and third condensing lenses 86 and 96 according to the fourth and fifth embodiments. According to the fourth and fifth embodiments, either one of the second and third condensing lenses 86 and 96 may be replaced with the spatial-mode filtering unit 108, or each of both of the second and third condensing lenses 86 and 96 may be replaced with the spatial-mode filtering unit 108.

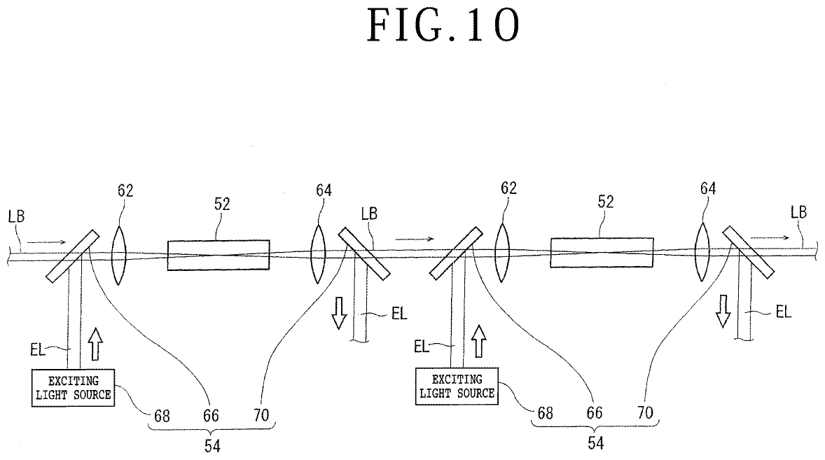

In each of the first through fifth embodiments, the laser oscillating device may include two or more units each including the laser medium 52 and the exciting light introducing unit 54, arranged in tandem, as illustrated in FIG. 10. The two or more units thus arranged are effective to increase the output power of the laser beam LB.

According to the fifth embodiment, the collimating lens 98 and the second mirror 106 are disposed at an end of the photonic crystal fiber 94. The collimating lens 98 and the second mirror 106 may be replaced with an end mirror 120 illustrated in FIG. 11 that closes the end of the photonic crystal fiber 94 such that the laser beam LB introduced into the photonic crystal fiber 94 from the other end thereof is shaped when it is reflected by the end mirror 120 and travels back through the photonic crystal fiber 94. The end mirror 120 may be vapor-deposited on or affixed to the other end of the photonic crystal fiber 94.

With the end mirror 120 held against the end of the photonic crystal fiber 94, a condensing lens 122 is disposed at the other end of the photonic crystal fiber 94. The laser beam LB is converged by the condensing lens 122 and introduced into the photonic crystal fiber 94. When the laser beam LB from the photonic crystal fiber 94 is reflected by the end mirror 120 and returns through the photonic crystal fiber 94, the condensing lens 122 functions as a collimating lens with respect to the laser beam returning from the photonic crystal fiber 94.

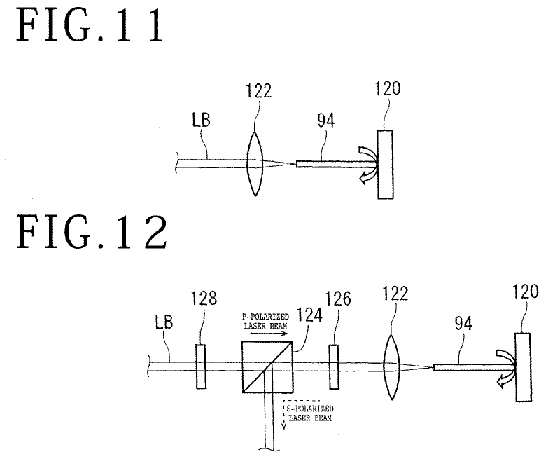

As illustrated in FIG. 12, a polarizing beam splitter 124 may be disposed in front of the condensing lens 122, and a quarter-wave plate 126 may be interposed between the condensing lens 122 and the polarizing beam splitter 124. The quarter-wave plate 126 may be replaced with a Faraday rotator. In addition, a half-wave plate 128 for adjusting the plane of polarization of the laser beam LB may be disposed in front of the polarizing beam splitter 124.

The half-wave plate 128 adjusts the plane of polarization of the laser beam LB to make the laser beam LB P-polarized with respect to the polarizing beam splitter 124. When the laser beam LB that has passed through the polarizing beam splitter 124 travels to and from the quarter-wave plate 126, the laser beam LB is converted from the P-polarized laser beam to an S-polarized laser beam. The S-polarized laser beam LB has its optical path changed by the polarizing beam splitter 124. Consequently, the laser beam LB that has been shaped twice by traveling to and from the photonic crystal fiber 94 can be introduced from the polarizing beam splitter 124 into another optical system.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A laser oscillating device for amplifying and emitting a laser beam, comprising:
a signal laser oscillator for emitting a laser beam;
a laser medium for amplifying the laser beam emitted from the signal laser oscillator;
an exciting light introducing unit for introducing an exciting light into the laser medium; and
a photonic crystal fiber for shaping the laser beam.

2. The laser oscillating device according to claim 1, wherein the photonic crystal fiber is interposed between the signal laser oscillator and the laser medium.

3. The laser oscillating device according to claim 1, wherein the photonic crystal fiber is disposed behind the laser medium.

4. The laser oscillating device according to claim 1, further comprising:
a condensing lens for converging and introducing the laser beam into the photonic crystal fiber.

5. The laser oscillating device according to claim 2, further comprising:
a first condensing lens for converging the laser beam emitted from the signal laser oscillator and introducing the converged laser beam into the photonic crystal fiber;
a first collimating lens for rectifying the laser beam that has passed through the photonic crystal fiber into a collimated beam;
a second condensing lens for converging and introducing the laser beam that has passed through the first collimating lens into the laser medium; and
a second collimating lens for rectifying the laser beam that has passed through the laser medium into a collimated beam, wherein
the exciting light introducing unit includes:
a first dichroic mirror interposed between the first collimating lens and the second condensing lens, for transmitting the laser beam therethrough and reflecting light of other wavelengths,
an exciting light source for introducing the exciting light to the first dichroic mirror, and
a second dichroic mirror for transmitting therethrough the laser beam that has passed through the second collimating lens and reflecting and excluding the light of other wavelengths.

6. The laser oscillating device according to claim 3, further comprising:
a polarizing beam splitter for transmitting therethrough a P-polarized laser beam emitted from the signal laser oscillator;
a first condensing lens for converging and introducing the P-polarized laser beam that has passed through the polarizing beam splitter into the laser medium;
a first collimating lens for rectifying the P-polarized laser beam that has passed through the laser medium into a collimated beam;
a second condensing lens for converging and introducing the P-polarized laser beam that has passed through the first collimating lens into the photonic crystal fiber;
a second collimating lens for rectifying the P-polarized laser beam that has passed through the photonic crystal fiber into a collimated beam;
a mirror for reflecting the P-polarized laser beam that has passed through the second collimating lens back to the second collimating lens; and
a quarter-wave plate or a Faraday rotator interposed between the second collimating lens and the mirror, for converting a plane of polarization of the P-polarized laser beam into an S-polarized laser beam, wherein
the exciting light introducing unit includes:
a first dichroic mirror interposed between the polarizing beam splitter and the first condensing lens, for transmitting the laser beam therethrough and reflecting light of other wavelengths,
an exciting light source for introducing the exciting light to the first dichroic mirror, and
a second dichroic mirror interposed between the first collimating lens and the second condensing lens, for transmitting the laser beam therethrough and reflecting and excluding the light of other wavelengths, and wherein
the S-polarized laser beam that has been amplified is emitted from the polarizing beam splitter.

7. The laser oscillating device according to claim 6, further comprising:
a second photonic crystal fiber disposed on an optical path for the amplified S-polarized laser beam emitted from the polarizing beam splitter.

8. The laser oscillating device according to claim 4, wherein the condensing lens is replaced with a spatial-mode filtering unit for introducing the laser beam into the photonic crystal fiber.

9. The laser oscillating device according to claim 8, wherein the spatial-mode filtering unit includes a pinhole mask, and a filtering condensing lens for condensing and introducing the laser beam that has passed through the pin-hole mask into the photonic crystal fiber.

10. The laser oscillating device according to claim 8, wherein the spatial-mode filtering unit includes a pinhole mask, a first filtering condensing lens for condensing the laser beam to be introduced into the pinhole mask, a filtering collimating lens for rectifying the laser beam that has passed through the pinhole mask into a collimated beam, and a second filtering condensing lens for converging and introducing the collimated laser beam into the photonic crystal fiber.

11. The laser oscillating device according to claim 1, wherein the exciting light introducing unit includes a first dichroic mirror for transmitting the laser beam therethrough and reflecting light of other wave-lengths, an exciting light source for introducing the exciting light to the first dichroic mirror, and a second dichroic mirror for transmitting therethrough the laser beam that has passed through the laser medium and reflecting and excluding the light of other wavelengths.

12. The laser oscillating device according to claim 1, further comprising:
two or more units each including the laser medium and the exciting light introducing unit, which are arranged in tandem.

13. The laser oscillating device according to claim 1, further comprising:
an end mirror closing an end of the photonic crystal fiber such that the laser beam introduced into the photonic crystal fiber from the other end thereof is shaped when it is reflected by the end mirror and travels back through the photonic crystal fiber.

14. The laser oscillating device according to claim 13, further comprising:
a condensing lens disposed at the other end of the photonic crystal fiber and functioning as a collimating lens with respect to the laser beam reflected by the end mirror and returning from the photonic crystal fiber.

15. The laser oscillating device according to claim 14, further comprising:
a polarizing beam splitter disposed in front of the condensing lens; and
a quarter-wave plate or a Faraday rotator interposed between the condensing lens and the polarizing beam splitter.

16. The laser oscillating device according to claim 3, further comprising:
a first polarizing beam splitter for transmitting therethrough a P-polarized laser beam emitted from the signal laser oscillator;
a first Faraday rotator and a half-wave plate for jointly converting a plane of polarization of the P-polarized laser beam;
a second polarizing beam splitter for transmitting the P-polarized laser beam therethrough;
a first condensing lens for converging and introducing the P-polarized laser beam that has passed through the second polarizing beam splitter into the laser medium;
a first collimating lens for rectifying the P-polarized laser beam that has passed through the laser medium into a collimated beam;
a second condensing lens for converging and introducing the P-polarized laser beam that has passed through the first collimating lens into the first photonic crystal fiber;
a second collimating lens for rectifying the P-polarized laser beam that has passed through the first photonic crystal fiber into a collimated beam;
a first mirror for reflecting the P-polarized laser beam that has passed through the second collimating lens back to the second collimating lens;
a quarter-wave plate or a second Faraday rotator interposed between the second collimating lens and the first mirror, for converting the plane of polarization of the P-polarized laser beam into an S-polarized laser beam;
the second photonic crystal fiber being disposed on an optical path branched off at the second polarizing beam splitter; and
a second mirror for reflecting the S-polarized laser beam that has passed through the second photonic crystal fiber back to the second photonic crystal fiber, wherein
the exciting light introducing unit includes:
a first dichroic mirror interposed between the second polarizing beam splitter and the first condensing lens, for transmitting the laser beam therethrough and reflecting light of other wavelengths,
an exciting light source for introducing the exciting light to the first dichroic mirror, and
a second dichroic mirror interposed between the first collimating lens and the second condensing lens, for transmitting the laser beam therethrough and reflecting and excluding the light of other wavelengths,
wherein the photonic crystal fiber includes a first photonic crystal fiber and a second photonic crystal fiber,
the S-polarized laser beam from the quarter-wave plate or the second Faraday rotator is introduced from the second polarizing beam splitter into the second photonic crystal fiber and is reflected by the second mirror to return from the second photonic crystal fiber to the second polarizing beam splitter,
the S-polarized laser beam that has returned to the second polarizing beam splitter passes through the first dichroic mirror, the first condensing lens, the laser medium, the first collimating lens, the second dichroic mirror, the second condensing lens, the first photonic crystal fiber, the second collimating lens, and the quarter-wave plate or the second Faraday rotator, and is reflected back by the first mirror,
the plane of polarization of the S-polarized laser beam reflected back by the first mirror is converted from the S-polarized laser beam into a P-polarized laser beam by passing through the quarter-wave plate or the second Faraday rotator, and
the P-polarized laser beam passes through the second polarizing beam splitter and thereafter is converted into an S-polarized laser beam by passing through the half-wave plate and the first Faraday rotator, and the S-polarized laser beam is emitted from the first polarizing beam splitter.

17. The laser oscillating device according to claim 16, wherein an end of the second photonic crystal fiber is closed by an end mirror and the laser beam introduced into the second photonic crystal fiber from the other end thereof is shaped when it is reflected by the end mirror and travels back through the photonic crystal fiber.
